(19) United States
(12) Patent Application Publication
(10) Pub. No.: US 2026/0186083 A1
(43) Pub. Date: Jul. 2, 2026

(54) MAGNETORESISTIVE ELEMENT AND MAGNETIC SENSOR

(71) Applicant: TDK CORPORATION, Tokyo (JP)

(72) Inventors: Hidekazu KOJIMA, Tokyo (JP); Satoshi MIURA, Tokyo (JP); Norikazu OTA, Tokyo (JP); Hiraku HIRABAYASHI, Tokyo (JP)

(73) Assignee: TDK CORPORATION, Tokyo (JP)

(21) Appl. No.: 19/416,377

(22) Filed: Dec. 11, 2025

(30) Foreign Application Priority Data
Dec. 26, 2024 (JP) 2024-229820

(51) Int. Cl. G01R 33/09

(52) U.S. Cl. CPC G01R 33/093

(57) ABSTRACT

An MR element includes: a magnetization pinned layer in which a direction of magnetization is fixed; a free layer configured to be capable of including a magnetic vortex structure and configured so that a center of the magnetic vortex structure can move in accordance with a target magnetic field; and a gap layer arranged between the magnetization pinned layer and the free layer. The magnetization pinned layer includes a first region and a second region in which the directions of the magnetization of the magnetization pinned layer are less aligned than the first region. The free layer is arranged so that an area of an overlapping part in which the free layer and the first region overlap each other when viewed in a stacking direction of the magnetization pinned layer, the gap layer, and the free layer is larger than an area of an overlapping part in which the free layer and the second region overlap each other when viewed in the stacking direction.

### CROSS REFERENCE TO RELATED APPLICATIONS

This application claims the benefit of Japanese Priority Patent Application No. 2024-229820 filed on Dec. 26, 2024, the entire contents of which are incorporated herein by reference.

### BACKGROUND

The disclosure relates to a magnetoresistive element including a free layer configured to be capable of including a magnetic vortex structure, and a magnetic sensor including the magnetoresistive element.

In recent years, magnetic sensors have been used for a variety of applications. Examples of known magnetic sensors include one that uses a spin-valve magnetoresistive element. The spin-valve magnetoresistive element includes a magnetization pinned layer in which a direction of magnetization is fixed, a free layer in which a direction of magnetization is variable in accordance with a direction of a target magnetic field, and a gap layer arranged between the magnetization pinned layer and the free layer.

Examples of known free layers used for the magnetoresistive element include one that is configured to be capable of including a magnetic vortex structure (also referred to as a vortex structure). For example, JP 2017-112375 A, JP 2017-191841 A, and U.S. Patent Application Publication No. 2024/0133982 disclose a magnetoresistive element including a free layer having a disk-like shape that is configured to be capable of including the magnetic vortex structure. In the magnetoresistive element including the free layer having the magnetic vortex structure as described in JP 2017-112375 A, JP 2017-191841 A, and U.S. Patent Application Publication No. 2024/0133982, the center of the magnetic vortex structure moves in accordance with a magnetic field being a detection target, whereby a resistance value of the magnetoresistive element changes.

The magnetic sensor may be used in various environments, and thus a strong magnetic field other than a detection target magnetic field may be temporarily applied to the magnetoresistive element. A phenomenon in which the strong magnetic field other than the detection target magnetic field is temporarily applied is hereinafter referred to as magnetic shock (Mag shock). When the magnetoresistive element is subjected to magnetic shock, directions of magnetization of the magnetization pinned layer may change from a state before being subjected to the magnetic shock. When the magnetoresistive element is subjected to the magnetic shock, the magnetic vortex structure of the free layer may temporarily disappear. Consequently, a detection signal generated by the magnetoresistive element may deviate from a specific value, inhibiting desired characteristics from being achieved.

### SUMMARY

A magnetoresistive element of a first aspect according to one embodiment of the disclosure includes: a magnetization pinned layer in which a direction of magnetization is fixed; a free layer configured to be capable of including a magnetic vortex structure and configured so that a center of the magnetic vortex structure can move in accordance with a target magnetic field; and a gap layer arranged between the magnetization pinned layer and the free layer. The magnetization pinned layer includes a first region and a second region in which the directions of the magnetization are less aligned than the first region. The free layer is arranged so that an area of an overlapping part in which the free layer and the first region overlap each other when viewed in a stacking direction of the magnetization pinned layer, the gap layer, and the free layer is larger than an area of an overlapping part in which the free layer and the second region overlap each other when viewed in the stacking direction.

A magnetoresistive element of a second aspect according to one embodiment of the disclosure includes: a magnetization pinned layer in which a direction of magnetization is fixed; two free layers each configured to be capable of including a magnetic vortex structure and configured so that a center of the magnetic vortex structure can move in accordance with a target magnetic field, and a gap layer arranged between the magnetization pinned layer and the two free layers. The magnetization pinned layer includes a first region and a second region in which the directions of the magnetization are less aligned than the first region. Each of the two free layers is arranged so that an area of an overlapping part in which each of the two free layers and the first region overlap each other when viewed in a stacking direction of the magnetization pinned layer, the gap layer, and the two free layers is larger than an area of an overlapping part in which each of the two free layers and the second region overlap each other when viewed in the stacking direction.

A magnetic sensor of a first aspect according to one embodiment of the disclosure includes: a power supply port; a ground port; an output port; a first resistor section arranged between the power supply port and the output port; and a second resistor section arranged between the ground port and the output port. Each of the first resistor section and the second resistor section includes a plurality of magnetism detection elements. Each of the plurality of magnetism detection elements is the magnetoresistive element according to one embodiment of the disclosure.

A magnetic sensor of a second aspect according to one embodiment of the disclosure is configured to detect a target magnetic field and generate at least one detection signal. The magnetic sensor includes: a power supply port; a ground port; an output port; a first resistor section arranged between the power supply port and the output port; and a second resistor section arranged between the ground port and the output port. Each of the first resistor section and the second resistor section includes a plurality of magnetoresistive elements. Each of the plurality of magnetoresistive elements includes a magnetization pinned layer in which a direction of magnetization is fixed, a free layer configured to be capable of including a magnetic vortex structure and configured so that a center of the magnetic vortex structure can move in accordance with the target magnetic field, and a gap layer arranged between the magnetization pinned layer and the free layer. A planar shape of the magnetization pinned layer is larger than a planar shape of the free layer. The at least one detection signal has correspondence with a potential of the output port, and has a specific value in a state in which strength of the target magnetic field is zero. Each of the plurality of magnetoresistive elements is configured so that a difference between the specific value before a strong magnetic field other than the target magnetic field is temporarily applied to the magnetic sensor and the specific value after the strong magnetic field is temporarily applied is smaller than a difference in a case in which the planar shape of the magnetization pinned layer is assumed to be same as the planar shape of the free layer.

Objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a plan view showing a magnetic sensor according to a first example embodiment of the disclosure.

FIG. 2 is a circuit diagram showing a circuit configuration of the magnetic sensor according to the first example embodiment of the disclosure.

FIG. 3 is a plan view showing a part of the magnetic sensor according to the first example embodiment of the disclosure.

FIG. 4 is a plan view showing a magnetoresistive element according to the first example embodiment of the disclosure.

FIG. 5 is a cross-sectional diagram showing the magnetoresistive element according to the first example embodiment of the disclosure.

FIG. 6 is an explanatory diagram showing directions of magnetization of a free layer of the magnetoresistive element according to the first example embodiment of the disclosure.

FIG. 7 is an explanatory diagram showing directions of magnetization of the free layer when a target magnetic field is applied to the magnetoresistive element according to the first example embodiment of the disclosure.

FIG. 8 is an explanatory diagram showing directions of magnetization of the free layer when a target magnetic field is applied to the magnetoresistive element according to the first example embodiment of the disclosure.

FIG. 9 is an explanatory diagram showing a relationship between strength of a magnetic field component and magnetization magnitude of the entire free layer in the first example embodiment of the disclosure.

FIG. 10 is an explanatory diagram showing directions of magnetization of a magnetization pinned layer of the magnetoresistive element according to the first example embodiment of the disclosure.

FIG. 11 is an explanatory diagram showing directions of magnetization of the magnetization pinned layer after a strong magnetic field other than the target magnetic field is temporarily applied to the magnetoresistive element according to the first example embodiment of the disclosure.

FIG. 12 is a cross-sectional diagram showing the magnetoresistive element of a comparative example.

FIG. 13 is a perspective view showing the magnetoresistive element according to a second example embodiment of the disclosure.

FIG. 14 is a plan view showing the magnetoresistive element according to the second example embodiment of the disclosure.

FIG. 15 is a cross-sectional diagram showing the magnetoresistive element according to a third example embodiment of the disclosure.

FIG. 16 is a cross-sectional diagram showing the magnetoresistive element according to a fourth example embodiment of the disclosure.

FIG. 17 is a plan view showing a first example of a planar shape of the magnetization pinned layer in the fourth example embodiment of the disclosure.

FIG. 18 is a plan view showing a second example of a planar shape of the magnetization pinned layer in the fourth example embodiment of the disclosure.

FIG. 19 is a cross-sectional diagram showing the magnetoresistive element according to a fifth example embodiment of the disclosure.

FIG. 20 is a cross-sectional diagram showing the magnetoresistive element according to a sixth example embodiment of the disclosure.

FIG. 21 is a cross-sectional diagram showing the magnetoresistive element according to a seventh example embodiment of the disclosure.

FIG. 22 is a plan view showing the magnetoresistive element according to the seventh example embodiment of the disclosure.

FIG. 23 is a cross-sectional diagram showing the magnetoresistive element according to an eighth example embodiment of the disclosure.

FIG. 24 is a cross-sectional diagram showing the magnetoresistive element according to a ninth example embodiment of the disclosure.

FIG. 25 is a cross-sectional diagram showing the magnetoresistive element according to a tenth example embodiment of the disclosure.

FIG. 26 is a cross-sectional diagram showing the magnetoresistive element according to an eleventh example embodiment of the disclosure.

FIG. 27 is a cross-sectional diagram showing the magnetoresistive element according to a twelfth example embodiment of the disclosure.

### DETAILED DESCRIPTION

An object of the disclosure is to provide a magnetoresistive element including a free layer including a magnetic vortex structure, which is a magnetoresistive element that can reduce variation of a detection signal generated after being subjected to magnetic shock, and a magnetic sensor including the magnetoresistive element.

In the following, some example embodiments and modification examples of the disclosure will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

### First Example Embodiment

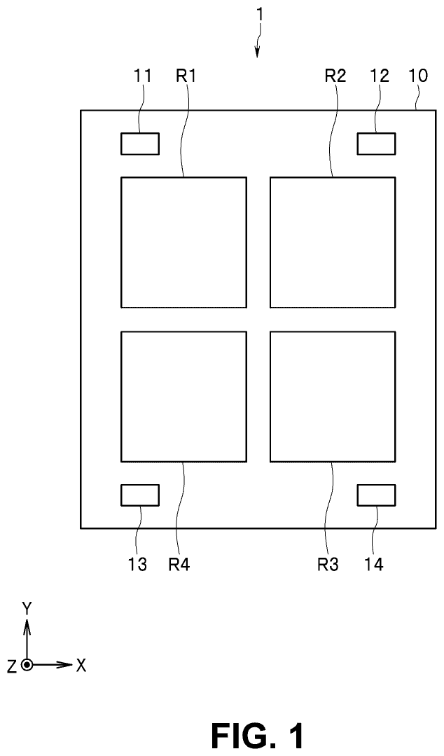

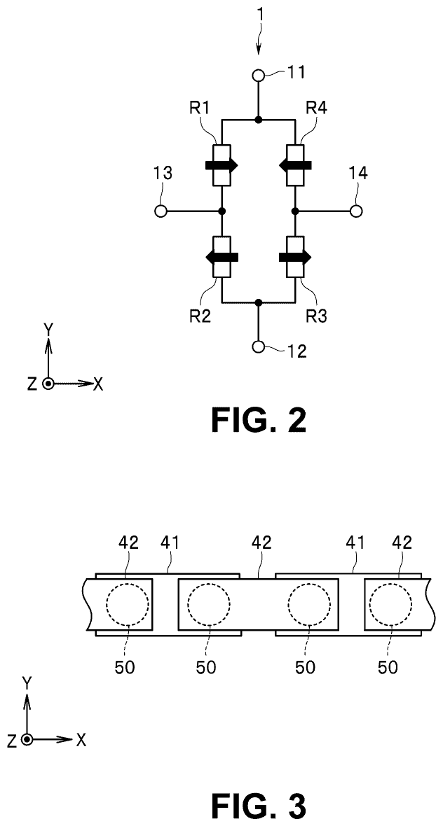

First, with reference to FIGS. 1 and 2, a schematic configuration of a magnetic sensor according to a first example embodiment of the disclosure is described. FIG. 1 is a plan view showing the magnetic sensor according to the example embodiment. FIG. 2 is a circuit diagram showing a circuit configuration of the magnetic sensor according to the example embodiment.

The magnetic sensor 1 according to the example embodiment is configured to detect a target magnetic field MF and generate at least one detection signal. The magnetic sensor 1 includes a power supply port 11, a ground port 12, a first output port 13, a second output port 14, a first resistor section R1, a second resistor section R2, a third resistor section R3, a fourth resistor section R4, and a substrate 10. The first to fourth resistor sections R1 to R4 and a plurality of terminals respectively corresponding to the power supply port 11, the ground port 12, and the first and second output ports 13 and 14 are provided on the substrate 10.

Each of the first to fourth resistor sections R1 to R4 includes a plurality of magnetism detection elements, and is configured to detect the target magnetic field MF and generate at least one detection signal. In the example embodiment, in particular, the plurality of magnetism detection elements correspond to a plurality of magnetoresistive elements (hereinafter referred to as MR elements) 50. Because each of the first to fourth resistor sections R1 to R4 includes the plurality of MR elements 50, it can also be said that the magnetic sensor 1 includes the plurality of MR elements 50.

As shown in FIG. 2, the first resistor section R1 is provided between the power supply port 11 and the first output port 13 in the circuit configuration. The second resistor section R2 is provided between the ground port 12 and the first output port 13 in the circuit configuration. The third resistor section R3 is provided between the ground port 12 and the second output port 14 in the circuit configuration. The fourth resistor section R4 is provided between the power supply port 11 and the second output port 14 in the circuit configuration. Note that, in the application, the expression “in the (a) circuit configuration” is used to indicate an arrangement in a circuit diagram, not an arrangement in a physical configuration.

A voltage or an electric current having specific magnitude is applied to the power supply port 11. The ground port 12 is connected to the ground.

Here, as shown in FIG. 1, an X direction, a Y direction, and a Z direction are defined. The X direction, the Y direction, and the Z direction are orthogonal to one another. The opposite directions to the X, Y, and Z directions will be expressed as −X, −Y, and −Z directions, respectively. In the example embodiment, in particular, a direction perpendicular to the surface of the substrate 10 is referred to as the Z direction.

As used herein, the term “above” refers to positions located ahead a certain reference position in the Z direction, and “below” refers to positions opposite from the “above” positions with respect to the certain reference position. For each component of the magnetic sensor 1, a surface located at an end in the Z direction is referred to as an “upper surface”, and a surface located at an end in the −Z direction is referred to as a “lower surface”. The expression “when viewed in a direction (e.g., the Z direction)” means that an object is viewed from a position away in a specific direction or in one direction parallel to the specific direction, i.e., the object is viewed in plan view.

FIG. 1 shows an example of an arrangement of the first to fourth resistor sections R1 to R4. In this example, the first and second resistor sections R1 and R2 are arranged in a direction parallel to the X direction. The second resistor section R2 is arranged forward of the first resistor section R1 in the X direction.

The third and fourth resistor sections R3 and R4 are arranged in a direction parallel to the X direction. The fourth resistor section R4 is arranged forward of the third resistor section R3 in the −X direction. The third resistor section R3 is arranged forward of the second resistor section R2 in the −Y direction. The fourth resistor section R4 is arranged forward of the first resistor section R1 in the −Y direction.

Note that the arrangement of the first to fourth resistor sections R1 to R4 is not limited to the example shown in FIG. 1. For example, the first to fourth resistor sections R1 to R4 may be arranged in a specific order in the direction parallel to the X direction or in a direction parallel to the Y direction.

Next, a specific structure of the magnetic sensor 1 is described in detail with reference to FIG. 3. FIG. 3 is a plan view showing a part of the magnetic sensor 1.

Each of the first to fourth resistor sections R1 to R4 further includes a plurality of lower electrodes 41 and a plurality of upper electrodes 42. The plurality of lower electrodes 41 are arranged above the substrate 10 (see FIG. 1). The plurality of MR elements 50 are arranged above the plurality of lower electrodes 41. The plurality of upper electrodes 42 are arranged above the plurality of MR elements 50. The plurality of lower electrodes 41 and the plurality of upper electrodes 42 are formed of a conductive material such as Cu, for example.

The plurality of MR elements 50 may be connected in series to each other by the plurality of lower electrodes 41 and the plurality of upper electrodes 42. In this case, a method of connecting the plurality of MR elements 50 is as follows. As shown in FIG. 3, each individual lower electrode 41 has an elongated shape. A gap is formed between two lower electrodes 41 adjacent in a longitudinal direction of the lower electrodes 41. On the top surface of the lower electrode 41, the MR elements 50 are respectively arranged near both ends in the longitudinal direction. Each individual upper electrode 42 has an elongated shape, and is arranged above two lower electrodes 41 adjacent in the longitudinal direction of the lower electrodes 41 and electrically connects the two adjacent MR elements 50 to each other. In such a manner, the plurality of MR elements 50 are connected in series.

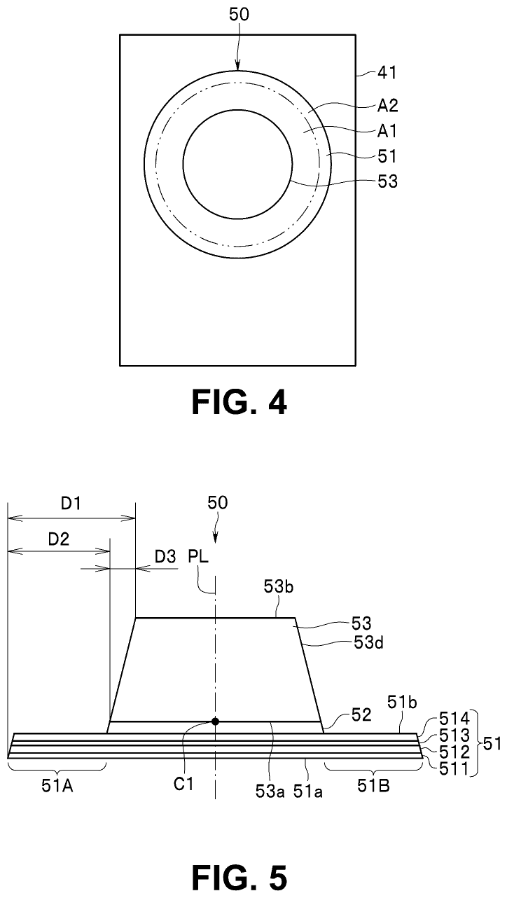

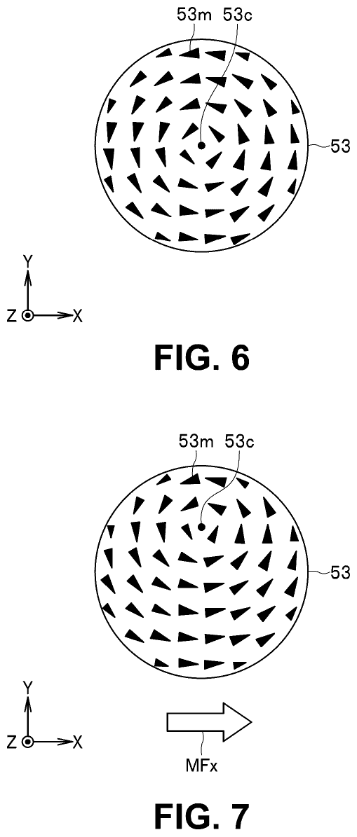

Next, a configuration of the MR element 50 is described with reference to FIGS. 4 to 6. FIG. 4 is a plan view showing the MR element 50. FIG. 5 is a cross-sectional diagram showing the MR element 50. FIG. 6 is an explanatory diagram showing directions of magnetization of a free layer of the MR element 50.

The MR element 50 includes a magnetization pinned layer 51 in which a direction of magnetization 51m is fixed, a free layer 53, and a gap layer 52 arranged between the magnetization pinned layer 51 and the free layer 53. A material and a shape of the free layer 53 are selected so that the free layer 53 can have a magnetic vortex structure (also referred to as a vortex structure). The gap layer 52 is a tunnel barrier layer or a nonmagnetic conductive layer. The MR element 50 may further include a cap layer (not shown) arranged above the free layer 53.

In the example embodiment, the magnetization pinned layer 51 is arranged above the lower electrode 41. The upper electrode 42 is arranged above the free layer 53.

At least a part of the free layer 53 has a truncated cone-like shape or a substantially truncated cone-like shape. In the example shown in FIG. 5, a part being a combination of the whole free layer 53 and the gap layer 52 has a truncated cone-like shape or a substantially truncated cone-like shape.

As shown in FIG. 5, the free layer 53 includes a bottom surface 53a and a top surface 53b located at both ends in a direction parallel to the Z direction, i.e., a stacking direction of the magnetization pinned layer 51, the gap layer 52, and the free layer 53, and a side surface 53d connecting the bottom surface 53a and the top surface 53b. The bottom surface 53a is located at an end of the free layer 53 in the −Z direction, and faces the magnetization pinned layer 51. The top surface 53b is a surface on an opposite side of the bottom surface 53a, and is located at an end of the free layer 53 in the Z direction.

The side surface 53d may include an inclined part that is inclined relative to the stacking direction. The side surface 53d may further include a part parallel to or substantially parallel to the Z direction. In the example shown in FIG. 5, the entire or substantially entire side surface 53d corresponds to the inclined part. The side surface 53d may be a planar surface, or may be a curved surface. The planar shape of the side surface 53d when viewed in one direction parallel to the stacking direction, i.e., the Z direction, is an annular shape. The planar shape of each of the bottom surface 53a and the top surface 53b is a circular shape or a substantially circular shape. The planar shape of the top surface 53b is smaller than the planar shape of the bottom surface 53a.

In FIG. 5, a symbol C1 denotes the centroid of the free layer 53 (the centroid of the planar shape of the free layer 53) when viewed in the direction parallel to the Z direction, i.e., the stacking direction. The centroid C1 of the free layer 53 may match the centroid of the bottom surface 53a of the free layer 53 when viewed in the stacking direction. In FIG. 5, for the sake of convenience, the centroid of the bottom surface 53a of the free layer 53 corresponds to the centroid C1 of the free layer 53.

The gap layer 52 includes a bottom surface and a top surface located at both ends in the direction parallel to the Z direction, i.e., the stacking direction, and a side surface connecting the bottom surface and the top surface. The bottom surface of the gap layer 52 is located at an end of the gap layer 52 in the −Z direction, and faces the magnetization pinned layer 51. The top surface of the gap layer 52 is a surface on an opposite side of the bottom surface, and faces the free layer 53. The side surface of the gap layer 52 may be continuous with the side surface 53d of the free layer 53. In this case, the side surface of the gap layer 52 may be inclined relative to the stacking direction.

The magnetization pinned layer 51 includes a bottom surface 51a and a top surface 51b located at both ends in the stacking direction. The top surface 51b is located at an end of the magnetization pinned layer 51 in the Z direction, and faces the free layer 53. The bottom surface 51a is a surface on an opposite side of the top surface 51b, and is located at an end of the magnetization pinned layer 51 in the −Z direction.

The magnetization pinned layer 51 further includes a side surface connecting the bottom surface 51a and the top surface 51b. The side surface of the magnetization pinned layer 51 is not continuous with the side surface of the gap layer 52. The side surface of the magnetization pinned layer 51 may or may not be inclined relative to the stacking direction.

The planar shape of the magnetization pinned layer 51 is larger than the planar shape of the free layer 53. Here, as shown in FIG. 5, an interval D1, an interval D2, and an interval D3 are defined as follows. FIG. 5 shows a cross-section of the MR element 50 in a cross-section that intersects the magnetization pinned layer 51 and the free layer 53 and is parallel to the stacking direction. The intervals D1 to D3 are intervals in the cross-section. The interval D1 is an interval between an outer edge of the bottom surface 51a of the magnetization pinned layer 51 in a direction orthogonal to the stacking direction and an outer edge of the top surface 53b of the free layer 53. The interval D2 is an interval between an outer edge of the bottom surface 51a of the magnetization pinned layer 51 in the direction orthogonal to the stacking direction and an outer edge of the bottom surface 53a of the free layer 53. The interval D3 is an interval between an outer edge of the bottom surface 53a of the free layer 53 in the direction orthogonal to the stacking direction and an outer edge of the top surface 53b of the free layer 53. The interval D1 may be larger than the interval D2. The interval D2 may be larger than the interval D3.

The magnetization pinned layer 51 includes a first part 51A and a second part 51B located on both sides of the free layer 53 in the direction orthogonal to the stacking direction. In the example embodiment, in particular, the first part 51A and the second part 51B are located on both sides of the free layer 53 in any direction orthogonal to the stacking direction. A dimension of the first part 51A in the stacking direction and a dimension of the second part 51B in the stacking direction may be the same.

In FIG. 5, a symbol PL denotes a virtual plane that passes through the centroid C1 of the free layer 53 and is parallel to the stacking direction. The magnetization pinned layer 51 may have a symmetrical shape with reference to the virtual plane PL.

The magnetization pinned layer 51 includes a first ferromagnetic layer 512 and a second ferromagnetic layer 514 each formed of a ferromagnetic material and a nonmagnetic layer 513 formed of a nonmagnetic material arranged between the first ferromagnetic layer 512 and the second ferromagnetic layer 514. The second ferromagnetic layer 514 is arranged between the first ferromagnetic layer 512 and the free layer 53. The first ferromagnetic layer 512 and the second ferromagnetic layer 514 are formed of CoFe, CoFeB, or CoNiFe, for example. The nonmagnetic layer 513 is formed of Ru, for example.

The magnetization pinned layer 51 further includes an antiferromagnetic layer 511 formed of an antiferromagnetic material. The antiferromagnetic layer 511 is arranged between the lower electrode 41 and the first ferromagnetic layer 512. The antiferromagnetic layer 511 is formed of IrMn, for example.

In the first ferromagnetic layer 512, the direction of magnetization is fixed due to exchange coupling with the antiferromagnetic layer 511. The first ferromagnetic layer 512 and the second ferromagnetic layer 514 are antiferromagnetically coupled, and the direction of magnetization is fixed in directions opposite to each other. The nonmagnetic layer 513 induces antiferromagnetic exchange coupling between the first ferromagnetic layer 512 and the second ferromagnetic layer 514, and fixes the directions of magnetization of the first ferromagnetic layer 512 and the directions of magnetization of the second ferromagnetic layer 514 to directions opposite to each other. When the magnetization pinned layer 51 includes the first ferromagnetic layer 512, the nonmagnetic layer 513, and the second ferromagnetic layer 514, the directions of magnetization of the magnetization pinned layer 51 refer to the directions of magnetization of the second ferromagnetic layer 514.

FIG. 6 shows directions of magnetization of the free layer 53 in any cross-section parallel to a plane (XY plane) orthogonal to the stacking direction. The free layer 53 has magnetization 53m that forms a vortex pattern centered around the magnetic vortex structure center 53c. When there is no magnetic field applied to the MR element 50, the magnetic vortex structure center 53c matches or substantially matches the axis of the truncated cone.

The free layer 53 is configured so that the magnetic vortex structure center 53c can move in accordance with the target magnetic field MF. The magnetic vortex structure center 53c moves when a component, which is in a direction orthogonal to the Z direction, of the target magnetic field MF is applied to the free layer 53. Within the range of change in the strength of the component, it is preferred that the free layer 53 is not saturated.

In the example embodiment, the magnetization 51m of the magnetization pinned layer 51 includes a component in the direction parallel to the X direction. Note that, when the magnetization 51m of the magnetization pinned layer 51 includes a component in a specific direction, the component in the specific direction may be the main component of the magnetization 51m of the magnetization pinned layer 51. In the example embodiment, when the magnetization 51m of the magnetization pinned layer 51 includes the component in the specific direction, the directions of the magnetization 51m of the magnetization pinned layer 51 correspond to or substantially correspond to the specific direction.

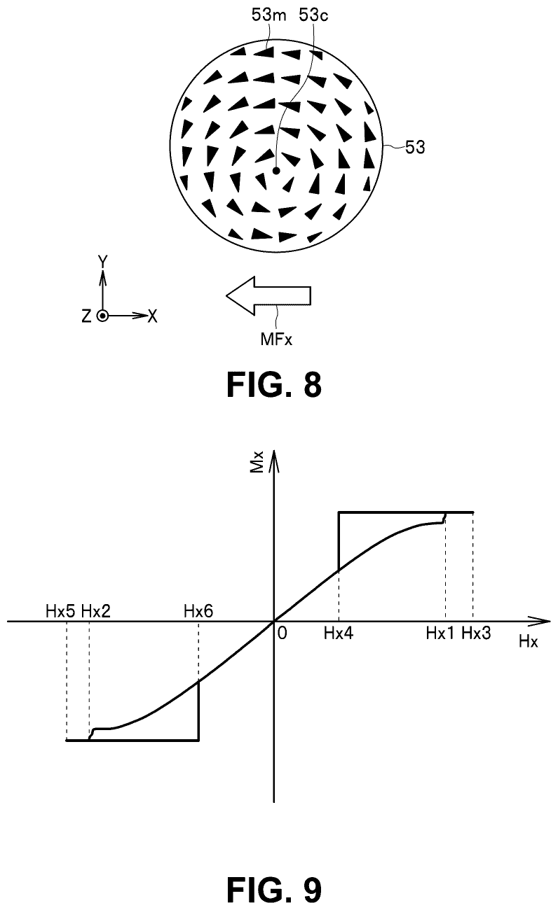

Here, the resistance value of the MR element 50 is described while focusing on a case in which the directions of the magnetization 51m of the magnetization pinned layer 51 correspond to the X direction, as an example. FIGS. 7 and 8 show the free layer 53 when a magnetic field component MFx, which is in the direction parallel to the X direction, of the target magnetic field MF is applied to the free layer 53.

FIG. 7 shows the free layer 53 when the direction of the magnetic field component MFx is the X direction. In this case, the magnetic vortex structure center 53c moves due to the magnetic field component MFx, and an amount of the magnetization 53m oriented in the X direction is more than an amount of the magnetization 53m oriented in the −X direction. In this case, the resistance value of the MR element 50 is reduced.

FIG. 8 shows the free layer 53 when the direction of the magnetic field component MFx is the −X direction. In this case, the magnetic vortex structure center 53c moves due to the magnetic field component MFx, and the amount of the magnetization 53m oriented in the −X direction is more than the amount of the magnetization 53m oriented in the X direction. In this case, the resistance value of the MR element 50 is increased.

A change amount of the resistance value of the MR element 50 depends on the strength of the magnetic field component MFx. When the direction of the magnetic field component MFx is the X direction, and the strength of the magnetic field component MFx is increased, the amount of the magnetization 53m oriented in the X direction is increased. The resistance value of the MR element 50 is reduced as the amount of the magnetization 53m oriented in the X direction is increased. When the direction of the magnetic field component MFx is the −X direction, and the strength of the magnetic field component MFx is increased, the amount of the magnetization 53m oriented in the −X direction is increased. The resistance value of the MR element 50 is increased as the amount of the magnetization 53m oriented in the −X direction is increased. As the strength of the magnetic field component MFx is increased, the resistance value of the MR element 50 changes so that a reduction amount or an increase amount thereof is increased. As the strength of the magnetic field component MFx is reduced, the resistance value of the MR element 50 changes so that a reduction amount or an increase amount thereof is reduced. In the example embodiment, in particular, the relationship between the strength of the magnetic field component MFx and the resistance value of the MR element 50 is a linear relationship or a substantially linear relationship as long as a condition where the free layer 53 is not saturated is satisfied.

Next, with reference to FIG. 9, a relationship between the strength of the magnetic field component MFx and magnetization magnitude of the entire free layer 53 is described. FIG. 9 is an explanatory diagram schematically showing the relationship between the strength of the magnetic field component MFx and the magnitude of the magnetization of the entire free layer 53. In FIG. 9, the horizontal axis represents strength Hx of the magnetic field component MFx, and the vertical axis represents magnetization magnitude Mx of the entire free layer 53. In FIG. 9, the strength Hx when the direction of the magnetic field component MFx is the X direction is represented by a positive value, and the strength Hx when the direction of the magnetic field component MFx is the −X direction is represented by a negative value. When the direction of the magnetic field component MFx is the X direction, and the amount of the magnetization 53m oriented in the X direction is increased, the magnetization magnitude Mx of the entire free layer 53 is increased. When the direction of the magnetic field component MFx is the −X direction, and the amount of the magnetization 53m oriented in the −X direction is increased, the magnetization magnitude Mx of the entire free layer 53 is reduced.

First, description is made on a case in which the strength Hx is increased from 0. When the strength Hx is gradually increased from 0, the magnetization magnitude Mx is gradually increased. When the strength Hx is equal to or greater than a value Hx1, as the magnetic vortex structure disappears, the magnetization magnitude Mx is constant, and the free layer 53 is magnetically saturated.

Next, description is made on a case in which the strength Hx is reduced from 0. When the strength Hx is gradually reduced from 0, the magnetization magnitude Mx is also gradually reduced. When the strength Hx is equal to or less than a value Hx2, as the magnetic vortex structure disappears, the magnetization magnitude Mx is constant, and the free layer 53 is magnetically saturated.

As shown in FIG. 9, within a specific range where the strength Hx is greater than the value Hx2 and is less than the value Hx1, the magnetization magnitude Mx changes linearly with respect to the change of the strength Hx. Note that the expression “to linearly change” indicates that the magnetization magnitude Mx with respect to the change of the strength Hx changes linearly or substantially linearly in the characteristic diagram showing the relationship between the strength Hx and the magnetization magnitude Mx.

In the example embodiment, within the change range of the strength Hx, it is preferred that the free layer 53 is not magnetically saturated while the magnetization magnitude Mx linearly changes with respect to the change of the strength Hx.

Note that, when the strength Hx is greater than the value Hx1 and the free layer 53 is magnetically saturated, and thereafter the strength Hx is reduced from a value Hx3 greater than the value Hx1, there is less change in the magnetization magnitude Mx until the strength Hx reaches a value Hx4 less than the value Hx1. When the strength Hx is less than the value Hx4, as the magnetic vortex structure is formed, the magnetization magnitude Mx linearly changes with respect to the change of the strength Hx similarly to a case in which the strength Hx changes within the specific range from the value Hx2 to the value Hx1.

Similarly, when the strength Hx is less than the value Hx2 and the free layer 53 is magnetically saturated, and thereafter the strength Hx is increased from a value Hx5 less than the value Hx2, there is less change in the magnetization magnitude Mx until the strength Hx reaches a value Hx6 greater than the value Hx2. When the strength Hx is greater than the value Hx6, as the magnetic vortex structure is formed, the magnetization magnitude Mx linearly changes with respect to the change of the strength Hx similarly to a case in which the strength Hx changes within the specific range from the value Hx2 to the value Hx1.

Although not shown, the relationship between the strength Hx and the resistance value of the MR element 50 is similar to the relationship between the strength Hx and the magnitude of the magnetization of the entire free layer 53.

Next, with reference to FIG. 2, the direction of the magnetization 51m of the magnetization pinned layer 51 in each of the first to fourth resistor sections R1 to R4 is described. The magnetization 51m of the magnetization pinned layer 51 of each of the plurality of MR elements 50 in the first resistor section R1 includes a component in a first magnetization direction. The magnetization 51m of the magnetization pinned layer 51 of each of the plurality of MR elements 50 in the second resistor section R2 includes a component in a second magnetization direction opposite to the first magnetization direction. The magnetization 51m of the magnetization pinned layer 51 of each of the plurality of MR elements 50 in the third resistor section R3 includes a component in the first magnetization direction. The magnetization 51m of the magnetization pinned layer 51 of each of the plurality of MR elements 50 in the fourth resistor section R4 includes a component in the second magnetization direction. In FIG. 2, the two arrows that are shown in the first and third resistor sections R1 and R3 represent the first magnetization direction. In FIG. 2, the two arrows that are shown in the second and fourth resistor sections R2 and R4 represent the second magnetization direction. In the example embodiment, in particular, the first magnetization direction is the X direction, and the second magnetization direction is the −X direction.

Next, with reference to FIG. 2, at least one detection signal generated by the magnetic sensor 1 is described. When the direction of the magnetic field component MFx is the X direction, the resistance value of each of the plurality of MR elements 50 of the first and third resistor sections R1 and R3 is reduced, and the resistance value of each of the plurality of MR elements 50 of the second and fourth resistor sections R2 and R4 is increased, as compared to a state in which there is no magnetic field MFx. As a result, the resistance value of each of the first and third resistor sections R1 and R3 is reduced, and the resistance value of each of the second and fourth resistor sections R2 and R4 is increased.

When the direction of the magnetic field component MFx is the −X direction, the change in the resistance value of each of the first to fourth resistor sections R1 to R4 is opposite to that in the above-described case in which the direction of the magnetic field component MFx is the X direction.

As described above, when the direction and the strength of the magnetic field component MFx change, the resistance value of each of the first to fourth resistor sections R1 to R4 changes so that the resistance value of each of the first and third resistor sections R1 and R3 is increased while the resistance value of each of the second and fourth resistor sections R2 and R4 is reduced, or the resistance value of each of the first and third resistor sections R1 and R3 is reduced while the resistance value of each of the second and fourth resistor sections R2 and R4 is increased. With this, a potential of a connection point between the first and second resistor sections R1 and R2, i.e., a potential of the first output port 13, and a potential of a connection point between the third and fourth resistor sections R3 and R4, i.e., a potential of the second output port 14, change. The magnetic sensor 1 may generate a signal corresponding to the potential of the first output port 13 and a signal corresponding to the potential of the second output port 14, as detection signals. Alternatively, the magnetic sensor 1 may generate a signal corresponding to a potential difference between the first output port 13 and the second output port 14, as a detection signal. In this case, the magnetic sensor 1 may further include a differential amplifier (differential detector) that outputs the signal corresponding to the potential difference between the first output port 13 and the second output port 14, as the detection signal.

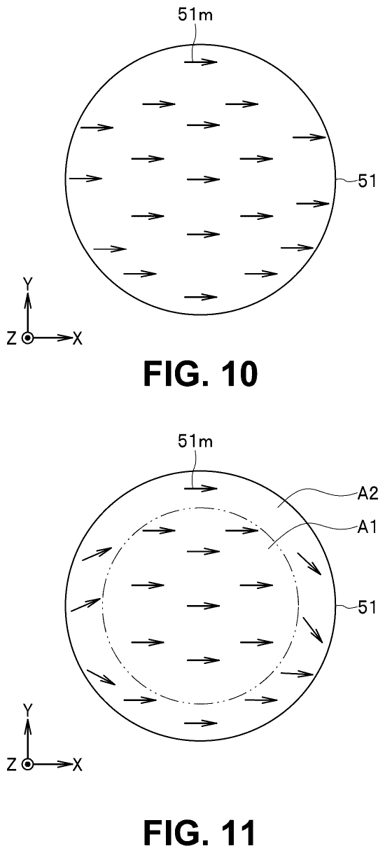

Next, with reference to FIGS. 10 and 11, a relationship between a phenomenon in which a strong magnetic field other than the target magnetic field MF is temporarily applied to the MR element 50, i.e., magnetic shock, and the magnetization 51m of the magnetization pinned layer 51 is described. FIG. 10 is an explanatory diagram showing the directions of the magnetization 51m of the magnetization pinned layer 51 of the MR element 50. FIG. 11 is an explanatory diagram showing the directions of the magnetization 51m of the magnetization pinned layer 51 after a strong magnetic field other than the target magnetic field MF is temporarily applied to the MR element 50, i.e., after the MR element 50 is subjected to magnetic shock. In FIGS. 10 and 11, the plurality of arrows represent directions of a plurality of magnetic moments corresponding to the magnetization 51m.

FIG. 10 shows a state of the magnetization pinned layer 51 in the magnetic sensor 1 immediately after manufacture or immediately after shipping, for example. As shown in FIG. 10, ideally, the directions of the plurality of magnetic moments corresponding to the magnetization 51m are the same regardless of positions in the magnetization pinned layer 51. In the example shown in FIG. 10, the directions of the plurality of magnetic moments correspond to the X direction regardless of positions in the magnetization pinned layer 51.

FIG. 11 shows a state of the magnetization pinned layer 51 in the magnetic sensor 1 after being subjected to magnetic shock. As shown in FIG. 11, after being subjected to magnetic shock, a part of the directions of the plurality of magnetic moments corresponding to the magnetization 51m may deviate from a specific direction. As a result, the directions of the plurality of magnetic moments differ depending on positions in the magnetization pinned layer 51.

In the state shown in FIG. 11, the magnetization pinned layer 51 includes a first region A1 and a second region A2. The first region A1 is a region in which the directions of the magnetization 51m are aligned. The “directions of the magnetization 51m are aligned” may refer to a state in which the directions of the magnetic moments corresponding to the magnetization 51m are the same or substantially the same, for example. The second region A2 is a region in which the directions of the magnetization 51m are less aligned than the first region A1. In the second region A2, the directions of the plurality of magnetic moments are disordered as compared to the first region A1. Here, the expression “directions of the magnetization 51m are less aligned” may refer, for example, to a state in which the directions of magnetic moments corresponding to the magnetization 51m are not uniform and may locally vary. Such a state may include cases where the directions of the magnetic moments are in a low degree of alignment (less aligned), or deviate from an originally aligned direction (misaligned).

Note that, in the first region A1, the directions of the plurality of magnetic moments need not be completely the same as long as a condition where the directions of the magnetization 51m are more aligned than the second region A2 is satisfied. In other words, as long as the condition is satisfied, the first region A1 may include a part in which the directions of the plurality of magnetic moments are disordered.

As shown in FIG. 11, the directions of the plurality of magnetic moments corresponding to the magnetization 51m are disordered in the vicinity of the outer edge of the bottom surface 51a of the magnetization pinned layer 51. In the vicinity of the outer edge of the bottom surface 51a of the magnetization pinned layer 51, a demagnetizing field increases, and thus the directions of the magnetic moments are prone to bend. Accordingly, the directions of the plurality of magnetic moments are prone to be disordered in the vicinity of the outer edge of the bottom surface 51a of the magnetization pinned layer 51, as compared to the center of the magnetization pinned layer 51 (the centroid of the planar shape of the magnetization pinned layer 51).

The second region A2 may include the outer edge of the bottom surface 51a of the magnetization pinned layer 51. In other words, the second region A2 may be defined as an annular region including the outer edge of the bottom surface 51a of the magnetization pinned layer 51. The first region A1 may be defined as a region located inside the second region A2.

Note that, in the state shown in FIG. 10, the entire magnetization pinned layer 51 corresponds to the first region A1. Thus, the first region A1 may be defined as a region in which the directions of the magnetization 51m are aligned before and after magnetic shock. The second region A2 may be defined as a region in which the directions of the magnetization 51m are misaligned after magnetic shock, i.e., a region in which the directions of the magnetization 51m may be disordered after magnetic shock. Here, the expression “directions of the magnetization 51m are less aligned” may refer to a state in which the directions of the magnetization 51m are not uniform and may locally vary.

In the example embodiment, in particular, the first region A1 includes a part of the antiferromagnetic layer 511, a part of the first ferromagnetic layer 512, a part of the nonmagnetic layer 513, and a part of the second ferromagnetic layer 514. The second region A2 includes another part of the antiferromagnetic layer 511, another part of the first ferromagnetic layer 512, another part of the nonmagnetic layer 513, and another part of the second ferromagnetic layer 514.

Next, with reference to FIG. 4, a relationship between the first and second regions A1 and A2 of the magnetization pinned layer 51 and the free layer 53 is described. The free layer 53 is arranged so that an area of a first overlapping part in which the free layer 53 and the first region A1 overlap each other when viewed in the direction parallel to the Z direction, i.e., the stacking direction, is larger than an area of a second overlapping part in which the free layer 53 and the second region A2 overlap each other when viewed in the stacking direction.

As long as a condition where the area of the first overlapping part is larger than the area of the second overlapping part is satisfied, the free layer 53 may or may not overlap the second region A2 when viewed in the stacking direction. In the latter case, the area of the free layer 53 having a planar shape may be the same as the area of the first region A1 having a planar shape, or may be smaller than the area of the first region A1 having a planar shape. In the latter case, the area of the second overlapping part is zero. In the example shown in FIG. 4, the free layer 53 is arranged to overlap only the first region A1 and not to overlap the second region A2 when viewed in the stacking direction.

Next, the operations and effects of the magnetic sensor 1 and the MR element 50 according to the example embodiment are described. In the example embodiment, as described above, the area of the first overlapping part is larger than the area of the second overlapping part. Consequently, according to the example embodiment, variation of at least one detection signal generated by the magnetic sensor 1 can be reduced. The effects are described below in comparison with an MR element of a comparative example.

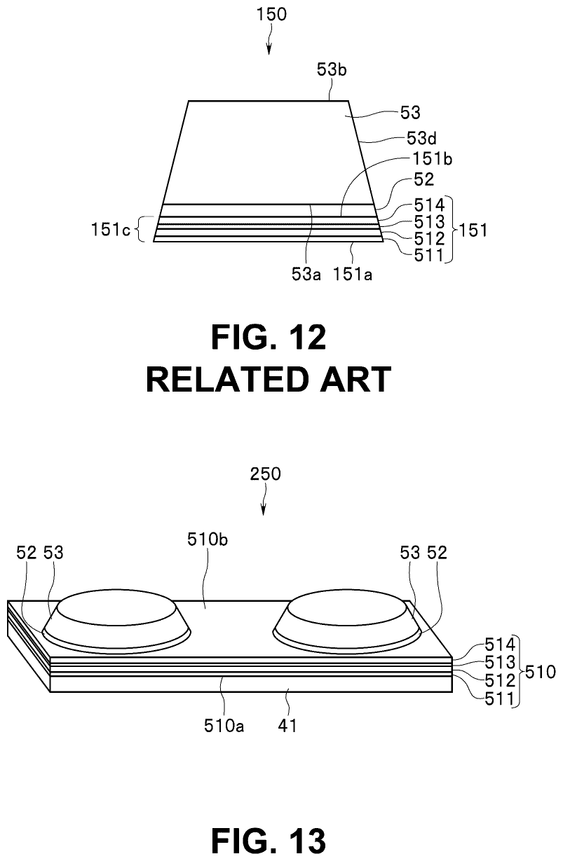

FIG. 12 is a cross-sectional diagram showing an MR element 150 of the comparative example. The MR element 150 of the comparative example includes a magnetization pinned layer 151 instead of the magnetization pinned layer 51 in the example embodiment. The magnetization pinned layer 151 includes a bottom surface 151a and a top surface 151b located at both ends in the stacking direction and a side surface 151c connecting the bottom surface 151a and the top surface 151b. The top surface 151b is located at an end of the magnetization pinned layer 151 in the Z direction, and faces the free layer 53. The bottom surface 151a is a surface on an opposite side of the top surface 151b, and is located at an end of the magnetization pinned layer 151 in the −Z direction. The side surface 151c is continuous with the side surface of the gap layer 52.

The planar shape of the magnetization pinned layer 151 is substantially the same as the planar shape of the free layer 53. The planar shape of the magnetization pinned layer 151 is smaller than the planar shape of the magnetization pinned layer 51 in the example embodiment, and has substantially the same size as the planar shape of the free layer 53.

Similarly to the magnetization pinned layer 51 in the example embodiment, the magnetization pinned layer 151 includes the antiferromagnetic layer 511, the first ferromagnetic layer 512, the nonmagnetic layer 513, and the second ferromagnetic layer 514.

Although not shown, similarly to the magnetization pinned layer 51 in the example embodiment, the magnetization pinned layer 151 includes the first region and the second region. The first region of the magnetization pinned layer 151 is a region corresponding to the first region A1 in the example embodiment, and is a region in which directions of magnetization of the magnetization pinned layer 151 are aligned. The second region of the magnetization pinned layer 151 is a region corresponding to the second region A2 in the example embodiment, and is a region in which directions of magnetization of the magnetization pinned layer 151 are misaligned. The free layer 53 overlaps the entire first region and substantially the entire second region when viewed in the direction parallel to the Z direction, i.e., the stacking direction.

Similarly to the magnetization pinned layer 51 in the example embodiment, in the MR element 150 of the comparative example, the first region and the second region appear after being subjected to magnetic shock. Here, a case is considered in which the magnetic shock has such magnitude as to disappear the magnetic vortex structure of the free layer 53. In this case, after the magnetic shock, the magnetic vortex structure of the free layer 53 is formed again. The magnetic vortex structure stabilizes in a first state or a second state. The first state is a state in which directions of the magnetization 53m of the free layer 53 stabilize in directions along a counterclockwise direction centered around the magnetic vortex structure center 53c as viewed in the Z direction. The second state is a state in which the directions of the magnetization 53m of the free layer 53 stabilize in directions along a clockwise direction centered around the magnetic vortex structure center 53c as viewed in the Z direction.

The resistance value of the MR element 150 may differ depending on whether the magnetic vortex structure is in the first state or the second state. Ideally, directions of a plurality of magnetic moments corresponding to the magnetization of the magnetization pinned layer 151 are the same. In actuality, however, the directions of the plurality of magnetic moments vary to some extent. In particular, in the second region of the magnetization pinned layer 151, the directions of the plurality of magnetic moments corresponding to the magnetization of the magnetization pinned layer 151 may not be symmetrical but biased in some direction. Accordingly, depending on whether the magnetic vortex structure is in the first state or the second state, an angle formed between the direction of each of the plurality of magnetic moments and the directions of the magnetization 53m of the free layer 53 may differ, and the resistance value of the MR element 150 may differ. In the MR element 150, the state of the magnetic vortex structure cannot be controlled, and thus the resistance value of the MR element 150 cannot be controlled.

Here, a magnetic sensor including a plurality of MR elements 150 of the comparative example is referred to as a magnetic sensor of the comparative example. The configuration of the magnetic sensor of the comparative example is the same as the configuration of the magnetic sensor 1 according to the example embodiment, except that the plurality of MR elements 150 are used instead of the plurality of MR elements 50. Similarly to the magnetic sensor 1 according to the example embodiment, the magnetic sensor of the comparative example is configured to generate at least one detection signal.

When standardization is conducted so that at least one detection signal has a maximum value of 1 and a minimum value of −1, a value of at least one detection signal in a state in which strength of the target magnetic field MF applied to the magnetic sensor of the comparative example is zero is ideally zero. In actuality, however, a phenomenon may occur in which the value of at least one detection signal in the state deviates from zero because the resistance value of the MR element 150 may differ as described above. The value of at least one detection signal deviating from zero is hereinafter referred to as an offset.

When the resistance value of the MR element 150 varies, the offset varies. In the comparative example, the directions of the plurality of magnetic moments corresponding to the magnetization of the magnetization pinned layer 151 change due to magnetic shock, and as a result, the offset may vary.

To address this, in the example embodiment, as described above, the free layer 53 is arranged so that the area of the first overlapping part is larger than the area of the second overlapping part. In other words, in the example embodiment, each of the plurality of MR elements 50 is configured so that a difference between the offset before being subjected to magnetic shock and the offset after being subjected to magnetic shock is smaller than a difference of a case in which the planar shape of the magnetization pinned layer 51 is assumed to be the same as the planar shape of the free layer 53 as in the MIR element 150 of the comparative example. Consequently, according to the example embodiment, influence of the plurality of magnetic moments corresponding to the magnetization 51m of the magnetization pinned layer 51, more specifically, influence of the plurality of magnetic moments with the directions being not symmetrical but biased in some direction in the second region A2, can be reduced. As a result, according to the example embodiment, variation of at least one detection signal due to magnetic shock including variation of the offset can be reduced.

Next, other effects in the example embodiment are described. In the example embodiment, the interval D1 between the outer edge of the bottom surface 51a of the magnetization pinned layer 51 and the outer edge of the top surface 53b of the free layer 53 is larger than the interval D2 between the outer edge of the bottom surface 51a of the magnetization pinned layer 51 and the outer edge of the bottom surface 53a of the free layer 53. According to the example embodiment, this can reduce influence of the second region A2 on a part of the free layer 53 in the vicinity of the top surface 53b.

Further, in the example embodiment, the interval D2 between the outer edge of the bottom surface 51a of the magnetization pinned layer 51 and the outer edge of the bottom surface 53a of the free layer 53 is larger than the interval D3 between the outer edge of the bottom surface 53a of the free layer 53 and the outer edge of the top surface 53b of the free layer 53. According to the example embodiment, the outer edge of the bottom surface 51a of the magnetization pinned layer 51 can be kept away from the free layer 53 as compared to a case in which the interval D2 is equal to or less than the interval D3. According to the example embodiment, this can reduce influence of the second region A2 on the free layer 53.

### Second Example Embodiment

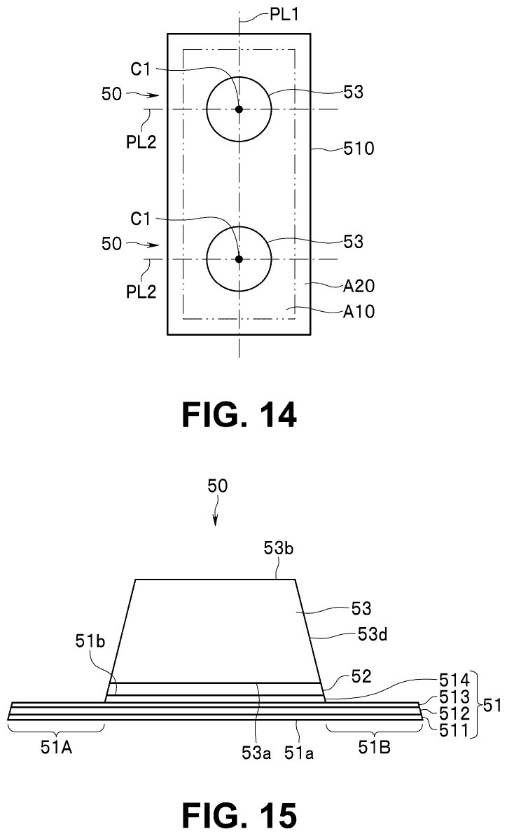

Next, with reference to FIGS. 13 and 14, a second example embodiment of the disclosure is described. FIG. 13 is a perspective view showing the MR element according to the example embodiment. FIG. 14 is a plan view showing the MR element according to the example embodiment.

The configuration of an MR element 250 according to the example embodiment is basically the same as the configuration of the MR element 50 according to the first example embodiment. Note that, in the MR element 250, the number of gap layers 52 and the number of free layers 53 are different from those of the first example embodiment. In other words, the MR element 250 includes a magnetization pinned layer 510 in which a direction of magnetization is fixed, two free layers 53, and two gap layers 52 arranged between the magnetization pinned layer 510 and the two free layers 53. The configuration, the shape, and the arrangement of each of the two gap layers 52 and the two free layers 53 are similar to those of the first example embodiment.

The magnetization pinned layer 510 faces the lower electrode 41. The planar shape of the magnetization pinned layer 510 may be the same as or different from the planar shape of the lower electrode 41. At least a part of the outer edge of the magnetization pinned layer 510 in a planar shape may match at least a part of the outer edge of the lower electrode 41 in a planar shape when viewed in the direction parallel to the Z direction, i.e., the stacking direction. In the example shown in FIGS. 13 and 14, the outer edge of the magnetization pinned layer 510 in a planar shape matches the outer edge of the lower electrode 41 in a planar shape when viewed in the stacking direction. More specifically, the outer edge of the bottom surface of the magnetization pinned layer 510 matches the outer edge of the top surface of the lower electrode 41 when viewed in the stacking direction.

The configuration of the magnetization pinned layer 510 is the same as the configuration of the magnetization pinned layer 51 in the first example embodiment, except for the shape. Similarly to the magnetization pinned layer 51, the magnetization pinned layer 510 includes the antiferromagnetic layer 511, the first ferromagnetic layer 512, the nonmagnetic layer 513, and the second ferromagnetic layer 514.

The magnetization pinned layer 510 includes a bottom surface 510a and a top surface 510b located at both ends in the stacking direction. The top surface 510b is located at an end of the magnetization pinned layer 510 in the Z direction. The bottom surface 510a is a surface on an opposite side of the top surface 510b, and is located at an end of the magnetization pinned layer 510 in the −Z direction.

A pair of one gap layer 52 and one free layer 53 and a pair of the other gap layer 52 and the other free layer 53 are arranged above the top surface 510b of the magnetization pinned layer 510 with an interval therebetween. The description on the intervals D1 to D3 in the first example embodiment applies to the example embodiment as well. By replacing the magnetization pinned layer 51 in the description on the intervals D1 to D3 in the first example embodiment with the magnetization pinned layer 510, description on the intervals D1 to D3 in the example embodiment is obtained.

As shown in FIG. 14, a first virtual plane PL1, which passes through the centroid C1 of each of the two free layers 53 and is parallel to each of the stacking direction and the directions in which the two free layers 53 are arrayed, and a second virtual plane PL2, which passes through the centroid C1 of one free layer 53 and is perpendicular to the first virtual plane PL1, are assumed. The magnetization pinned layer 510 may have a symmetrical shape with reference to the first virtual plane PL1. The magnetization pinned layer 510 has an asymmetrical shape with reference to the second virtual plane PL2.

The magnetization pinned layer 510 includes a first region A10 and a second region A20. The first region A10 corresponds to the first region A1 in the first example embodiment. The second region A20 corresponds to the second region A2 in the first example embodiment. The second region A20 is an annular region including the outer edge of the bottom surface 510a of the magnetization pinned layer 510. The first region A10 is located inside the second region A20.

The relationship between the first and second regions A1 and A2 of the magnetization pinned layer 51 and the free layer 53 described in the first example embodiment applies to the first and second regions A10 and A20 of the magnetization pinned layer 510 and the free layer 53 in the example embodiment as well. In the example shown in FIG. 14, the two free layers 53 arranged above the top surface 510b of the magnetization pinned layer 510 are arranged to overlap only the first region A10 and not to overlap the second region A20 when viewed in the stacking direction. When viewed in the stacking direction, the second region A20 need not be present in a region between the two free layers 53.

Note that, although not shown, in the example embodiment, a plurality of MR elements 250 are connected in series by the plurality of upper electrodes 42. Each of the plurality of upper electrodes 42 connects one free layer 53 of one of two MR elements 250 and one free layer 53 of the other of the two MR elements 250.

Other configurations, operations, and effects in the example embodiment are similar to those of the first example embodiment.

### Third Example Embodiment

Next, with reference to FIG. 15, a third example embodiment of the disclosure is described. FIG. 15 is a cross-sectional diagram showing the MR element according to the example embodiment. The configuration of the MR element 50 according to the example embodiment is different from that of the first example embodiment in the following respects. In the example embodiment, the planar shape of the second ferromagnetic layer 514 of the magnetization pinned layer 51 is substantially the same as the planar shape of the free layer 53. The planar shape of the second ferromagnetic layer 514 is smaller than the planar shape of each of the antiferromagnetic layer 511 and the first ferromagnetic layer 512 of the magnetization pinned layer 51 and has substantially the same size as the planar shape of the free layer 53.

Note that the planar shape of the nonmagnetic layer 513 may be substantially the same as the planar shape of the first ferromagnetic layer 512, or may be substantially the same as the planar shape of the second ferromagnetic layer 514. FIG. 15 shows the former example.

As described in the first example embodiment, the magnetization pinned layer 51 includes the first part 51A and the second part 51B located on both sides of the free layer 53 in the direction parallel to the Z direction, i.e., the direction orthogonal to the stacking direction. In the example embodiment, each of the first part 51A and the second part 51B includes a part of each of the antiferromagnetic layer 511 and the first ferromagnetic layer 512, but need not include the second ferromagnetic layer 514. At least a part of each of the first part 51A and the second part 51B includes the second region A2 described in the first example embodiment. The second region A2 includes a part of each of the antiferromagnetic layer 511 and the first ferromagnetic layer 512, but need not include the second ferromagnetic layer 514.

Other configurations, operations, and effects in the example embodiment are similar to those of the first example embodiment.

### Fourth Example Embodiment

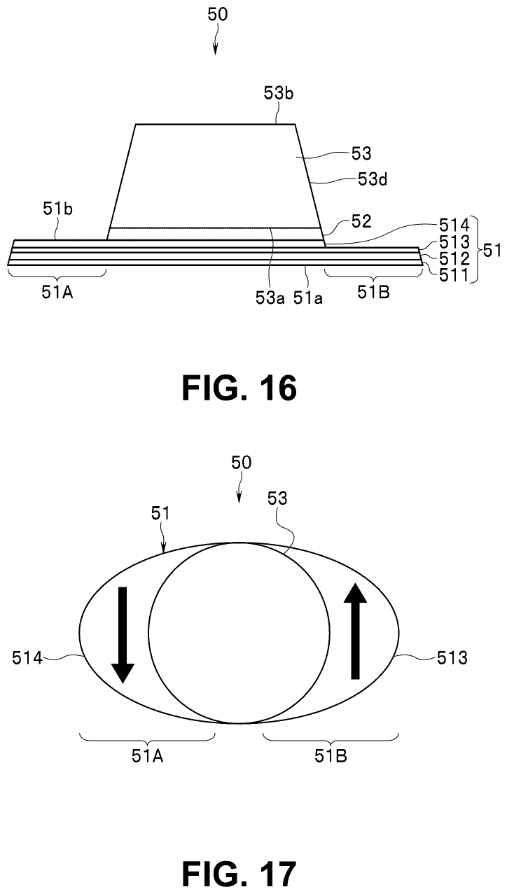

Next, with reference to FIG. 16, a fourth example embodiment of the disclosure is described. FIG. 16 is a cross-sectional diagram showing the MR element according to the example embodiment. The configuration of the MR element 50 according to the example embodiment is different from that of the first example embodiment in the following respects. As described in the first example embodiment, the magnetization pinned layer 51 of the MR element 50 includes the first part 51A and the second part 51B located on both sides of the free layer 53 in the direction parallel to the Z direction, i.e., the direction orthogonal to the stacking direction. In the example embodiment, a dimension of the first part 51A in the stacking direction and a dimension of the second part 51B in the stacking direction may be different from each other.

In the example shown in FIG. 16, the first part 51A includes the antiferromagnetic layer 511, the first ferromagnetic layer 512, the nonmagnetic layer 513, and the second ferromagnetic layer 514. The second part 51B includes the antiferromagnetic layer 511 and the first ferromagnetic layer 512, but does not include the second ferromagnetic layer 514. Thus, the dimension of the first part 51A in the stacking direction is larger than the dimension of the second part 51B in the stacking direction. Note that the second part 51B may or may not include the nonmagnetic layer 513. FIG. 16 shows the former example.

Next, the planar shape of the magnetization pinned layer 51 is described. First, with reference to FIG. 17, a first example of the planar shape of the magnetization pinned layer 51 is described. FIG. 17 is a plan view showing the first example of the planar shape of the magnetization pinned layer 51. In the first example, the planar shape of the magnetization pinned layer 51 has an elliptical shape that is elongated in a direction orthogonal to the direction of the magnetization 51m of the magnetization pinned layer 51.

The first ferromagnetic layer 512 includes a first overlapping part that overlaps the free layer 53 as viewed in the stacking direction and a first non-overlapping part that does not overlap the free layer 53 as viewed in the stacking direction. Each of the first part 51A and the second part 51B includes the first non-overlapping part of the first ferromagnetic layer 512.

The second ferromagnetic layer 514 includes a second overlapping part that overlaps the free layer 53 as viewed in the stacking direction and a second non-overlapping part that does not overlap the free layer 53 as viewed in the stacking direction. The first part 51A includes the second non-overlapping part of the second ferromagnetic layer 514, whereas the second part 51B does not include the second non-overlapping part of the second ferromagnetic layer 514.

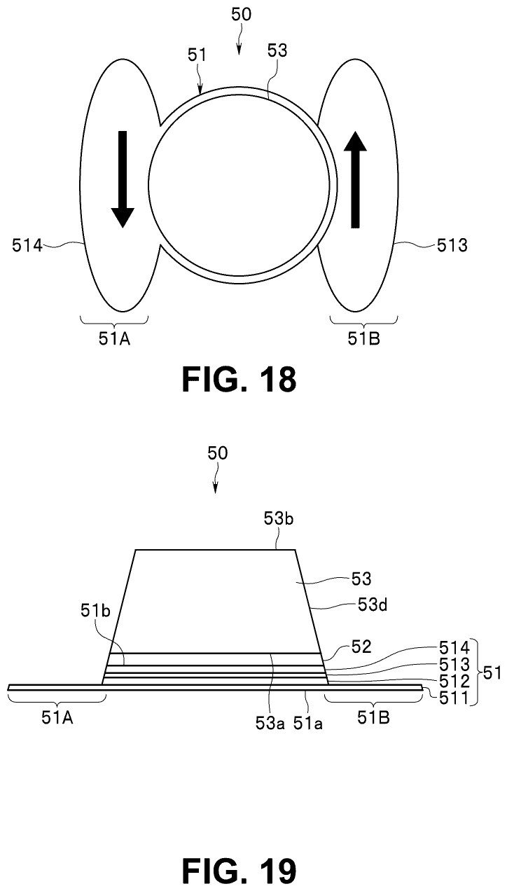

Next, with reference to FIG. 18, a second example of the planar shape of the magnetization pinned layer 51 is described. FIG. 18 is a plan view showing the second example of the planar shape of the magnetization pinned layer 51. In the second example, each of the first part 51A and the second part 51B of the magnetization pinned layer 51 has an elongated shape in a direction orthogonal to the direction in which the first part 51A and the second part 51B are arrayed. Other features in the structure of the magnetization pinned layer 51 in the second example are the same as those of the first example.

In FIGS. 17 and 18, the arrows shown in the first part 51A represent the directions of the magnetization of the second ferromagnetic layer 514 in the first part 51A. The arrows shown in the second part 51B represent the directions of the magnetization of the first ferromagnetic layer 512 in the second part 51B. In the example embodiment, the directions of the magnetization 51m of the magnetization pinned layer 51 are opposite on both sides of the free layer 53.

A leakage magnetic field generated due to the magnetization 51m of the magnetization pinned layer 51 is applied to the free layer 53. In the example embodiment, the direction of the leakage magnetic field is constant. When the magnetic vortex structure of the free layer 53 is formed again after being subjected to magnetic shock, the directions of the magnetization 53m of the free layer 53 may correspond to directions along the leakage magnetic field. As described above, because the direction of the leakage magnetic field is constant, the directions of the magnetization 53m of the free layer 53 can be made in the same directions. In other words, according to the example embodiment, the magnetic vortex structure can be selectively set to the first state or the second state described in the first example embodiment. Consequently, according to the example embodiment, variation of at least one detection signal due to magnetic shock including variation of the offset can be reduced.

Other configurations, operations, and effects in the example embodiment are similar to those of the first example embodiment.

### Fifth Example Embodiment

Next, with reference to FIG. 19, a fifth example embodiment of the disclosure is described. FIG. 19 is a cross-sectional diagram showing the MR element according to the example embodiment. In the example embodiment, the planar shape of each of the first ferromagnetic layer 512, the nonmagnetic layer 513, and the second ferromagnetic layer 514 of the magnetization pinned layer 51 is substantially the same as the planar shape of the free layer 53. The planar shape of each of the first ferromagnetic layer 512, the nonmagnetic layer 513, and the second ferromagnetic layer 514 is smaller than the planar shape of the antiferromagnetic layer 511 of the magnetization pinned layer 51, and has substantially the same size as the planar shape of the free layer 53.

As described in the first example embodiment, the magnetization pinned layer 51 includes the first part 51A and the second part 51B located on both sides of the free layer 53 in the direction parallel to the Z direction, i.e., the direction orthogonal to the stacking direction. In the example embodiment, each of the first part 51A and the second part 51B includes a part of the antiferromagnetic layer 511, but need not include the first ferromagnetic layer 512 and the second ferromagnetic layer 514. At least a part of each of the first part 51A and the second part 51B includes the second region A2 described in the first example embodiment. The second region A2 includes a part of the antiferromagnetic layer 511, but need not include the first ferromagnetic layer 512 and the second ferromagnetic layer 514.

Other configurations, operations, and effects in the example embodiment are similar to those of the first example embodiment.

### Sixth Example Embodiment

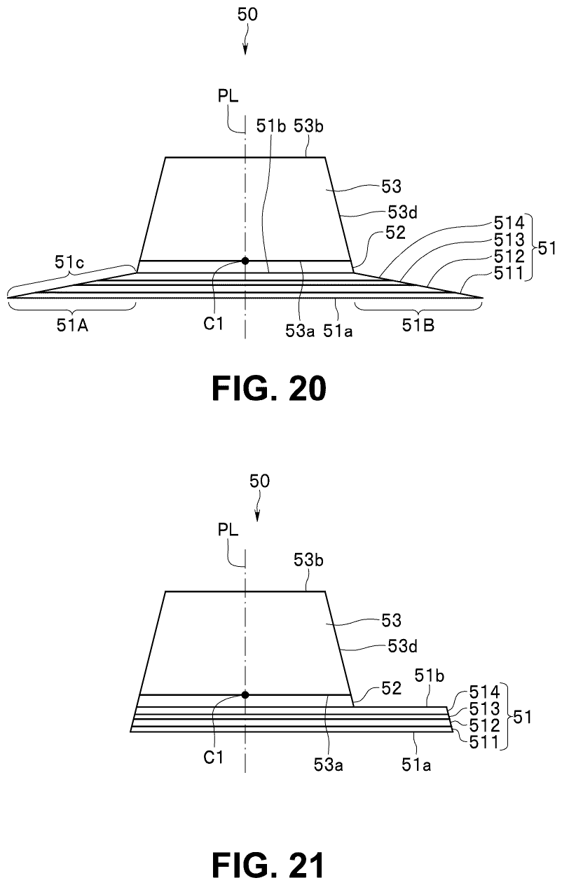

Next, with reference to FIG. 20, a sixth example embodiment of the disclosure is described. FIG. 20 is a cross-sectional diagram showing the MR element according to the example embodiment. The configuration of the MR element 50 according to the example embodiment is different from that of the first example embodiment in the following respects. In the example embodiment, the magnetization pinned layer 51 of the MR element 50 includes a side surface 51c connecting the bottom surface 51a and the top surface 51b of the magnetization pinned layer 51. The side surface 51c is greatly inclined relative to the direction parallel to the Z direction, i.e., the stacking direction, as compared to the side surface 53d of the free layer 53. An angle formed by the side surface 51c of the magnetization pinned layer 51 with respect to the bottom surface 51a of the magnetization pinned layer 51 is smaller than an angle formed by the side surface 53d of the free layer 53 with respect to the bottom surface 51a of the magnetization pinned layer 51.

Note that, when the virtual plane PL that passes through the centroid Cl of the free layer 53 and is parallel to the stacking direction is assumed, the magnetization pinned layer 51 may have a symmetrical shape with reference to the virtual plane PL, or may have an asymmetrical shape.

When the side surface 51c is present on one of the first part 51A and the second part 51B of the magnetization pinned layer 51, the side surface 51c need not be present on the other. In other words, the other of the first part 51A and the second part 51B may have a shape similar to that of one of the first, third, and fourth example embodiments.

Other configurations, operations, and effects in the example embodiment are similar to those of one of the first, third, and fourth example embodiments.

### Seventh Example Embodiment

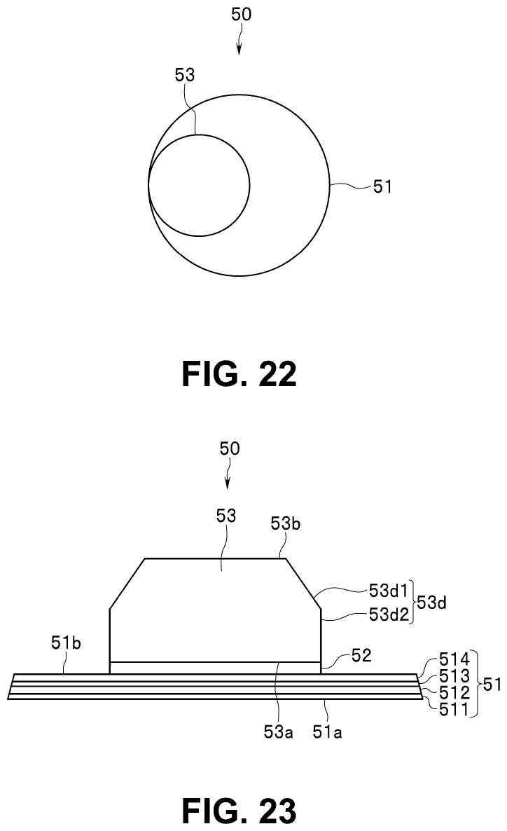

Next, with reference to FIGS. 21 and 22, a seventh example embodiment of the disclosure is described. FIG. 21 is a cross-sectional diagram showing the MR element according to the example embodiment. FIG. 22 is a plan view showing the MR element according to the example embodiment.

The configuration of the MR element 50 according to the example embodiment is different from that of the first example embodiment in the following respects. As shown in FIG. 21, a specific cross-section parallel to the Z direction, i.e., the stacking direction, is assumed. The specific cross-section may be a cross-section parallel to the direction of the magnetization 51m of the magnetization pinned layer 51. In the specific cross-section, the bottom surface 51a of the magnetization pinned layer 51 of the MR element 50 includes two end portions located at both ends in the direction orthogonal to the stacking direction. The free layer 53 of the MR element 50 is arranged so that an interval between the centroid C1 of the free layer 53 and one of the two end portions of the bottom surface 51a in the direction orthogonal to the stacking direction is smaller than an interval between the centroid C1 of the free layer 53 and the other of the two end portions of the bottom surface 51a in the direction orthogonal to the stacking direction.

In the specific cross-section, the bottom surface 53a of the free layer 53 includes two end portions located at both ends in the direction orthogonal to the stacking direction. In the example shown in FIGS. 21 and 22, as viewed in the stacking direction, the free layer 53 is arranged so that one of the two end portions of the bottom surface 53a overlaps one of the two end portions of the bottom surface 51a.

Here, the virtual plane PL that passes through the centroid C1 of the free layer 53 and is parallel to the stacking direction is assumed. In the example embodiment, in particular, the virtual plane PL is orthogonal to the specific cross-section. The magnetization pinned layer 51 may have an asymmetrical shape with reference to the virtual plane PL.

In the example embodiment, a leakage magnetic field generated due to the magnetization 51m of the magnetization pinned layer 51 is applied to the free layer 53. When the magnetic vortex structure of the free layer 53 is formed again after being subjected to magnetic shock, the directions of the magnetization 53m of the free layer 53 may correspond to directions along the leakage magnetic field. According to the example embodiment, the magnetic vortex structure can be selectively set to the first state or the second state described in the first example embodiment. Consequently, according to the example embodiment, variation of at least one detection signal due to magnetic shock including variation of the offset can be reduced.

Other configurations, operations, and effects in the example embodiment are similar to those of the first example embodiment.

### Eighth Example Embodiment

Next, with reference to FIG. 23, an eighth example embodiment of the disclosure is described. FIG. 23 is a cross-sectional diagram showing the MR element 50 according to the example embodiment. The configuration of the MR element 50 according to the example embodiment is different from that of the first example embodiment in the following respects. In the example embodiment, the side surface 53d of the free layer 53 of the MR element 50 includes a first surface 53d1 and a second surface 53d2 located between the first surface 53d1 and bottom surface 53a of the free layer 53.

A first angle formed by the second surface 53d2 with respect to the bottom surface 53a may be equal to or larger than a second angle formed by the first surface 53d1 with respect to the bottom surface 53a. In the example shown in FIG. 23, the first angle is larger than the second angle. The first angle may be 90° or substantially 90°.

Note that, in the example embodiment, as the magnetization pinned layer 51, the magnetization pinned layer 51 in one of the first to seventh example embodiments can be applied. Other configurations, operations, and effects in the example embodiment are similar to those of one of the first to seventh example embodiments.

### Ninth Example Embodiment

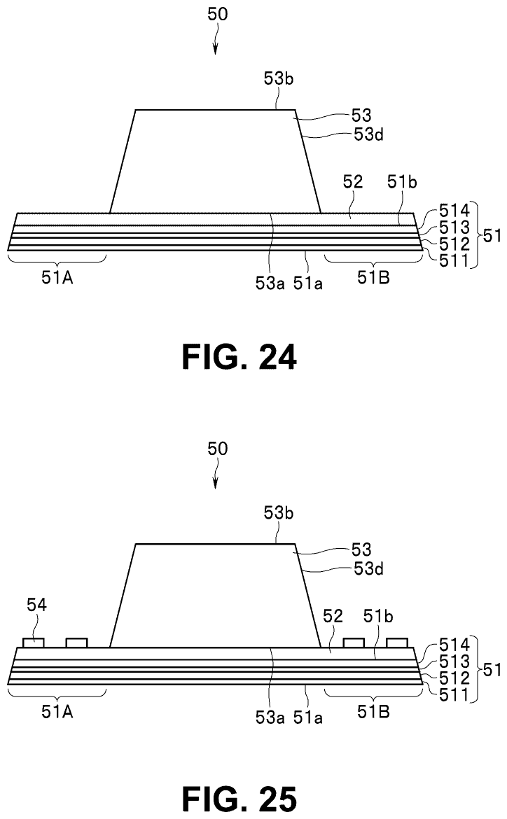

Next, with reference to FIG. 24, a ninth example embodiment of the disclosure is described. FIG. 24 is a cross-sectional diagram showing the MR element 50 according to the example embodiment.

The configuration of the MR element 50 according to the example embodiment is different from that of the first example embodiment in the following respects. In the example embodiment, the planar shape of the gap layer 52 of the MR element 50 may be larger than the planar shape of the free layer 53 of the MR element 50. When viewed in the direction parallel to the Z direction, i.e., the stacking direction, the gap layer 52 overlaps at least a part of each of the first part 51A and the second part 51B of the magnetization pinned layer 51 of the MR element 50.

In the example embodiment, in particular, the planar shape of the gap layer 52 of the MR element 50 is the same or substantially the same as the planar shape of the magnetization pinned layer 51 of the MR element 50. When viewed in the stacking direction, at least a part of the outer edge of the gap layer 52 in a planar shape may match at least a part of the outer edge of the magnetization pinned layer 51 in a planar shape. More specifically, when viewed in the stacking direction, at least a part of the outer edge of the bottom surface of the gap layer 52 may match at least a part of the outer edge of the top surface 51b of the magnetization pinned layer 51.

For example, the MR element 50 is formed by patterning a stacked body including the magnetization pinned layer 51, the gap layer 52, and the free layer 53. In the example embodiment, in particular, the magnetization pinned layer 51 and the free layer 53 are separately patterned so that the planar shape of the magnetization pinned layer 51 and the planar shape of the free layer 53 differ from each other. In patterning of the free layer 53 of the magnetization pinned layer 51, for example, ion beam etching is used. In the example embodiment, the free layer 53 is patterned so that the gap layer 52 is not etched and removed. According to the example embodiment, this can prevent the magnetization pinned layer 51 from being damaged by ion beams. As a result, according to the example embodiment, this can prevent the direction of the magnetization 51m of the magnetization pinned layer 51 from deviating from a desired direction due to patterning of the free layer 53.

Other configurations, operations, and effects in the example embodiment are similar to those of the first example embodiment.

### Tenth Example Embodiment

Next, with reference to FIG. 25, a tenth example embodiment of the disclosure is described. FIG. 25 is a cross-sectional diagram showing the MR element 50 according to the example embodiment.

The configuration of the MR element 50 according to the example embodiment is different from that of the ninth example embodiment in the following respects. The MR element 50 according to the example embodiment includes at least one structure 54 arranged above the gap layer 52. The at least one structure 54 contains a metal material. The metal material may be a magnetic metal material, or may be a nonmagnetic metal material. Alternatively, the at least one structure 54 may include both of a magnetic metal material and a nonmagnetic metal material. A dimension of the at least one structure 54 in the direction parallel to the Z direction, i.e., the stacking direction, may be smaller than a dimension of the free layer 53 in the stacking direction.

FIG. 25 shows an example in which the MR element 50 includes a plurality of structures 54. The plurality of structures 54 may be spaced apart from each other. Each of the plurality of structures 54 may have an elongated shape, or need not have an elongated shape. When each of the plurality of structures 54 has an elongated shape, the plurality of structures 54 may have a shape and an arrangement such that a striped pattern appears when viewed in the stacking direction.

As described in the ninth example embodiment, for example, the MR element 50 is formed by patterning a stacked body including the magnetization pinned layer 51, the gap layer 52, and the free layer 53. The stacked body includes a stacked film to later become the free layer 53. The plurality of structures 54 may be a part of the stacked film. In other words, the plurality of structures 54 may be a part of the stacked film left after patterning when the stacked film is patterned so that the stacked film becomes the free layer 53.

Other configurations, operations, and effects in the example embodiment are similar to those of the ninth example embodiment.

### Eleventh Example Embodiment

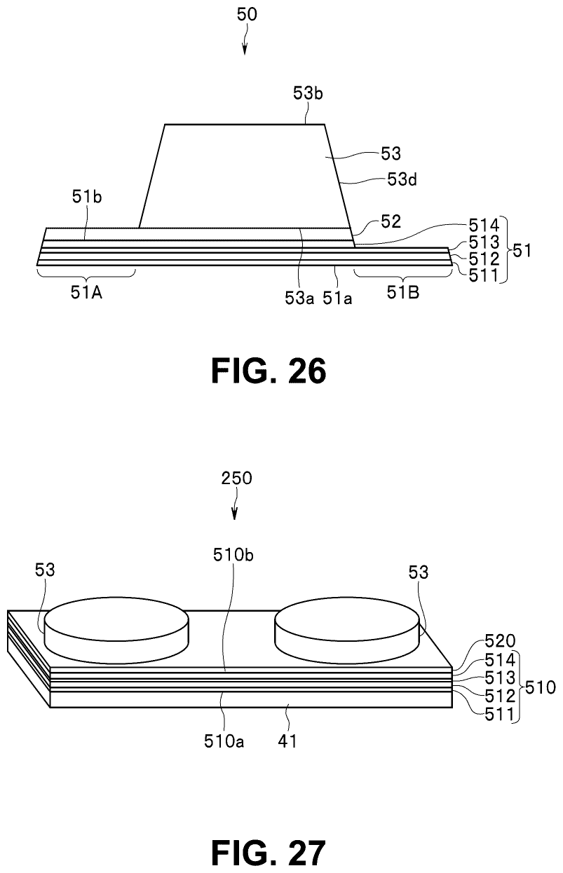

Next, with reference to FIG. 26, an eleventh example embodiment of the disclosure is described. FIG. 26 is a cross-sectional diagram showing the MR element 50 according to the example embodiment.

The configuration of the MR element 50 according to the example embodiment is different from that of the fourth example embodiment in the following respects. In the example embodiment, similarly to the ninth example embodiment, the planar shape of the gap layer 52 of the MR element 50 is larger than the planar shape of the free layer 53 of the MR element 50. In the example embodiment, in particular, when viewed in the direction parallel to the Z direction, i.e., the stacking direction, the gap layer 52 overlaps at least a part of the first part 51A of the magnetization pinned layer 51 of the MR element 50, but does not overlap the second part 51B of the magnetization pinned layer 51.

Note that, similarly to the tenth example embodiment, at least one structure 54 may be provided above a part of the gap layer 52 that overlaps the first part 51A when viewed in the stacking direction.

Similarly to the sixth example embodiment, one of the first part 51A and the second part 51B of the magnetization pinned layer 51 may include the side surface 51c greatly inclined relative to the direction parallel to the Z direction, i.e., the stacking direction.

Other configurations, operations, and effects in the example embodiment are similar to those of one of the fourth, sixth, ninth, and tenth example embodiments.

### Twelfth Example Embodiment

Next, with reference to FIG. 27, a twelfth example embodiment of the disclosure is described. FIG. 27 is a perspective view showing the MR element 250 according to the example embodiment.

The configuration of the MR element 250 according to the example embodiment is different from that of the second example embodiment in the following respects. The MR element 250 according to the example embodiment includes a gap layer 520 instead of the two gap layers 52 in the second example embodiment. Similarly to the gap layer 52, the gap layer 520 is a tunnel barrier layer or a nonmagnetic conductive layer.

The planar shape of the gap layer 520 is larger than the planar shape of the free layer 53. The planar shape of the gap layer 520 is the same or substantially the same as the planar shape of the magnetization pinned layer 510. The outer edge of the gap layer 520 in a planar shape matches the outer edge of the magnetization pinned layer 510 in a planar shape when viewed in the stacking direction. More specifically, the outer edge of the bottom surface of the gap layer 520 matches the outer edge of the top surface 510b of the magnetization pinned layer 510 when viewed in the stacking direction.

Note that, in FIG. 27, for the sake of convenience, the shape of the free layer 53 is a cylindrical shape. However, the shape of the free layer 53 is not limited to the cylindrical shape, and may be the same as the shape of the free layer 53 in the second example embodiment, or may be the same as the shape of the free layer 53 in the eighth example embodiment.

Although not shown, similarly to the MR element 50 according to the tenth example embodiment, the MR element 250 may include at least one structure arranged above the gap layer 520.

Other configurations, operations, and effects in the example embodiment are similar to those of one of the second, eighth, and tenth example embodiments.

Note that the disclosure is not limited to the foregoing example embodiments, and various modifications may be made thereto. For example, the shape of the side surface 53d of the free layer 53 of the MR element 50 is not limited to the example shown in the example embodiments. For example, the side surface 53d of the free layer 53 may include three or more parts whose inclined angles are different from each other.

The first magnetization direction described in the first example embodiment may correspond to the Y direction. The second magnetization direction described in the first example embodiment may correspond to the −Y direction.

As described above, a magnetoresistive element of a first aspect according to one embodiment of the disclosure includes: a magnetization pinned layer in which a direction of magnetization is fixed; a free layer configured to be capable of including a magnetic vortex structure and configured so that a center of the magnetic vortex structure can move in accordance with a target magnetic field; and a gap layer arranged between the magnetization pinned layer and the free layer. The magnetization pinned layer includes a first region and a second region in which the directions of the magnetization are less aligned than the first region. The free layer is arranged so that an area of an overlapping part in which the free layer and the first region overlap each other when viewed in a stacking direction of the magnetization pinned layer, the gap layer, and the free layer is larger than an area of an overlapping part in which the free layer and the second region overlap each other when viewed in the stacking direction.

In the magnetoresistive element of the first aspect according to one embodiment of the disclosure, the free layer may not overlap the second region when viewed in the stacking direction.

In the magnetoresistive element of the first aspect according to one embodiment of the disclosure, the magnetization pinned layer may include a first top surface facing the free layer and a first bottom surface on an opposite side of the first top surface. The second region may include an outer edge of the first bottom surface.

In the magnetoresistive element of the first aspect according to one embodiment of the disclosure, the free layer may include a second bottom surface facing the magnetization pinned layer and a second top surface on an opposite side of the second bottom surface. In a cross-section that intersects the magnetization pinned layer and the free layer and is parallel to the stacking direction, an interval between an outer edge of the first bottom surface and an outer edge of the second top surface in a direction orthogonal to the stacking direction may be larger than an interval between the outer edge of the first bottom surface and an outer edge of the second bottom surface in the direction orthogonal to the stacking direction.

In the magnetoresistive element of the first aspect according to one embodiment of the disclosure, in a cross-section that intersects the magnetization pinned layer and the free layer and is parallel to the stacking direction, an interval between an outer edge of the second bottom surface and an outer edge of the first bottom surface in a direction orthogonal to the stacking direction may be larger than an interval between the outer edge of the second bottom surface and an outer edge of the second top surface in the direction orthogonal to the stacking direction.

In the magnetoresistive element of the first aspect according to one embodiment of the disclosure, the magnetization pinned layer may include a first ferromagnetic layer and a second ferromagnetic layer each formed of a ferromagnetic material and a nonmagnetic layer formed of a nonmagnetic material arranged between the first ferromagnetic layer and the second ferromagnetic layer. The second ferromagnetic layer may be arranged between the first ferromagnetic layer and the free layer. The second region may include a part of the first ferromagnetic layer and a part of the second ferromagnetic layer. Alternatively, the second region may include a part of the first ferromagnetic layer but need not include the second ferromagnetic layer.

In the magnetoresistive element of the first aspect according to one embodiment of the disclosure, the magnetization pinned layer may further include an antiferromagnetic layer formed of an antiferromagnetic material and a ferromagnetic layer arranged above the antiferromagnetic layer and formed of a ferromagnetic material. The second region may include a part of the antiferromagnetic layer but may not include the ferromagnetic layer.

In the magnetoresistive element of the first aspect according to one embodiment of the disclosure, the free layer may include a bottom surface facing the magnetization pinned layer, a top surface on an opposite side of the bottom surface, and a side surface connecting the bottom surface and the top surface. The side surface may include a first surface and a second surface located between the first surface and the bottom surface. An angle formed by the second surface with respect to the bottom surface may be equal to or larger than an angle formed by the first surface with respect to the bottom surface.

In the magnetoresistive element of the first aspect according to one embodiment of the disclosure, the magnetization pinned layer may include a first part and a second part located on both sides of the free layer in a direction orthogonal to the stacking direction. A dimension of the first part in the stacking direction and a dimension of the second part in the stacking direction may be different from each other.

In the magnetoresistive element of the first aspect according to one embodiment of the disclosure, the magnetization pinned layer may have an asymmetrical shape with reference to a virtual plane that passes through a centroid of the free layer when viewed in the stacking direction and is parallel to the stacking direction.

In the magnetoresistive element of the first aspect according to one embodiment of the disclosure, the magnetization pinned layer may face an electrode. At least a part of an outer edge of the magnetization pinned layer in a planar shape may match at least a part of an outer edge of the electrode in a planar shape when viewed in the stacking direction.

In the magnetoresistive element of the first aspect according to one embodiment of the disclosure, a planar shape of the gap layer may be larger than a planar shape of the free layer. At least a part of an outer edge of the gap layer in the planar shape may match at least a part of an outer edge of the magnetization pinned layer in the planar shape when viewed in the stacking direction. The magnetoresistive element of the disclosure may include at least one structure containing a metal material and arranged above the gap layer. A dimension of the at least one structure in the stacking direction may be smaller than a dimension of the free layer in the stacking direction.

A magnetoresistive element of a second aspect according to one embodiment of the disclosure includes: a magnetization pinned layer in which a direction of magnetization is fixed; two free layers each configured to be capable of including a magnetic vortex structure and configured so that a center of the magnetic vortex structure can move in accordance with a target magnetic field, and a gap layer arranged between the magnetization pinned layer and the two free layers. The magnetization pinned layer includes a first region and a second region in which the directions of the magnetization are less aligned than the first region. Each of the two free layers is arranged so that an area of an overlapping part in which each of the two free layers and the first region overlap each other when viewed in a stacking direction of the magnetization pinned layer, the gap layer, and the two free layers is larger than an area of an overlapping part in which each of the two free layers and the second region overlap each other when viewed in the stacking direction.

A magnetic sensor of a first aspect according to one embodiment of the disclosure includes: a power supply port; a ground port; an output port; a first resistor section arranged between the power supply port and the output port; and a second resistor section arranged between the ground port and the output port. Each of the first resistor section and the second resistor section includes a plurality of magnetism detection elements. Each of the plurality of magnetism detection elements is the magnetoresistive element according to one embodiment of the disclosure.

A magnetic sensor of a second aspect according to one embodiment of the disclosure is configured to detect a target magnetic field and generate at least one detection signal. The magnetic sensor includes: a power supply port; a ground port; an output port; a first resistor section arranged between the power supply port and the output port; and a second resistor section arranged between the ground port and the output port. Each of the first resistor section and the second resistor section includes a plurality of magnetoresistive elements. Each of the plurality of magnetoresistive elements includes a magnetization pinned layer in which a direction of magnetization is fixed, a free layer configured to be capable of including a magnetic vortex structure and configured so that a center of the magnetic vortex structure can move in accordance with the target magnetic field, and a gap layer arranged between the magnetization pinned layer and the free layer. A planar shape of the magnetization pinned layer is larger than a planar shape of the free layer. The at least one detection signal has correspondence with a potential of the output port, and has a specific value in a state in which strength of the target magnetic field is zero. Each of the plurality of magnetoresistive elements is configured so that a difference between the specific value before a strong magnetic field other than the target magnetic field is temporarily applied to the magnetic sensor and the specific value after the strong magnetic field is temporarily applied is smaller than a difference in a case in which the planar shape of the magnetization pinned layer is assumed to be same as the planar shape of the free layer.

In the magnetoresistive element of the disclosure and the magnetic sensor of the first aspect of the disclosure, the free layer is arranged so that the area of the overlapping part in which the free layer and the first region overlap each other is larger than the area of the overlapping part in which the free layer and the second region overlap each other. Consequently, according to the disclosure, the magnetoresistive element and the magnetic sensor that can reduce variation of a detection signal generated after being subjected to magnetic shock can be implemented.

In the magnetic sensor of the second aspect of the disclosure, the planar shape of the magnetization pinned layer is larger than the planar shape of the free layer. Each of the plurality of magnetoresistive elements is configured so that a difference between the specific value before a strong magnetic field other than the target magnetic field is temporarily applied to the magnetic sensor and the specific value after the strong magnetic field is temporarily applied is smaller than a difference in a case in which the planar shape of the magnetization pinned layer is assumed to be same as the planar shape of the free layer. Consequently, according to the disclosure, the magnetic sensor that can reduce variation of a detection signal generated after being subjected to magnetic shock can be implemented.

It is apparent that the disclosure can be carried out in various forms and modifications in the light of the foregoing descriptions. Accordingly, within the scope of the following claims and equivalents thereof, the disclosure can be carried out in forms other than the foregoing example embodiments.

1. A magnetoresistive element comprising:
a magnetization pinned layer in which a direction of magnetization is fixed;
a free layer configured to be capable of including a magnetic vortex structure and configured so that a center of the magnetic vortex structure can move in accordance with a target magnetic field; and
a gap layer arranged between the magnetization pinned layer and the free layer, wherein
the magnetization pinned layer includes a first region and a second region in which the directions of the magnetization are less aligned than the first region, and
the free layer is arranged so that an area of an overlapping part in which the free layer and the first region overlap each other when viewed in a stacking direction of the magnetization pinned layer, the gap layer, and the free layer is larger than an area of an overlapping part in which the free layer and the second region overlap each other when viewed in the stacking direction.

2. The magnetoresistive element according to claim 1, wherein
the free layer does not overlap the second region when viewed in the stacking direction.

3. The magnetoresistive element according to claim 1, wherein
the magnetization pinned layer includes a first top surface facing the free layer and a first bottom surface on an opposite side of the first top surface, and
the second region includes an outer edge of the first bottom surface.

4. The magnetoresistive element according to claim 1, wherein
the magnetization pinned layer includes a first top surface facing the free layer and a first bottom surface on an opposite side of the first top surface,
the free layer includes a second bottom surface facing the magnetization pinned layer and a second top surface on an opposite side of the second bottom surface, and
in a cross-section that intersects the magnetization pinned layer and the free layer and is parallel to the stacking direction, an interval between an outer edge of the first bottom surface and an outer edge of the second top surface in a direction orthogonal to the stacking direction is larger than an interval between the outer edge of the first bottom surface and an outer edge of the second bottom surface in the direction orthogonal to the stacking direction.

5. The magnetoresistive element according to claim 1, wherein
the magnetization pinned layer includes a first top surface facing the free layer and a first bottom surface on an opposite side of the first top surface,
the free layer includes a second bottom surface facing the magnetization pinned layer and a second top surface on an opposite side of the second bottom surface, and
in a cross-section that intersects the magnetization pinned layer and the free layer and is parallel to the stacking direction, an interval between an outer edge of the second bottom surface and an outer edge of the first bottom surface in a direction orthogonal to the stacking direction is larger than an interval between the outer edge of the second bottom surface and an outer edge of the second top surface in the direction orthogonal to the stacking direction.

6. The magnetoresistive element according to claim 1, wherein
the magnetization pinned layer includes a first ferromagnetic layer and a second ferromagnetic layer each formed of a ferromagnetic material and a nonmagnetic layer formed of a nonmagnetic material arranged between the first ferromagnetic layer and the second ferromagnetic layer.

7. The magnetoresistive element according to claim 6, wherein
the second ferromagnetic layer is arranged between the first ferromagnetic layer and the free layer, and
the second region includes a part of the first ferromagnetic layer and a part of the second ferromagnetic layer.

8. The magnetoresistive element according to claim 6, wherein
the second ferromagnetic layer is arranged between the first ferromagnetic layer and the free layer, and
the second region includes a part of the first ferromagnetic layer but does not include the second ferromagnetic layer.

9. The magnetoresistive element according to claim 1, wherein
the magnetization pinned layer further includes an antiferromagnetic layer formed of an antiferromagnetic material and a ferromagnetic layer arranged above the antiferromagnetic layer and formed of a ferromagnetic material, and
the second region includes a part of the antiferromagnetic layer but does not include the ferromagnetic layer.

10. The magnetoresistive element according to claim 1, wherein
the free layer includes a bottom surface facing the magnetization pinned layer, a top surface on an opposite side of the bottom surface, and a side surface connecting the bottom surface and the top surface,
the side surface includes a first surface and a second surface located between the first surface and the bottom surface, and
an angle formed by the second surface with respect to the bottom surface is equal to or larger than an angle formed by the first surface with respect to the bottom surface.

11. The magnetoresistive element according to claim 1, wherein
the magnetization pinned layer includes a first part and a second part located on both sides of the free layer in a direction orthogonal to the stacking direction, and
a dimension of the first part in the stacking direction and a dimension of the second part in the stacking direction are different from each other.

12. The magnetoresistive element according to claim 1, wherein
the magnetization pinned layer has an asymmetrical shape with reference to a virtual plane that passes through a centroid of the free layer when viewed in the stacking direction and is parallel to the stacking direction.

13. The magnetoresistive element according to claim 1, wherein
the magnetization pinned layer faces an electrode, and
at least a part of an outer edge of the magnetization pinned layer in a planar shape matches at least a part of an outer edge of the electrode in a planar shape when viewed in the stacking direction.

14. The magnetoresistive element according to claim 1, wherein
a planar shape of the gap layer is larger than a planar shape of the free layer.

15. The magnetoresistive element according to claim 14, wherein
at least a part of an outer edge of the gap layer in the planar shape matches at least a part of an outer edge of the magnetization pinned layer in the planar shape when viewed in the stacking direction.

16. The magnetoresistive element according to claim 14, further comprising
at least one structure containing a metal material and arranged above the gap layer, wherein
a dimension of the at least one structure in the stacking direction is smaller than a dimension of the free layer in the stacking direction.

17. A magnetoresistive element comprising:
a magnetization pinned layer in which a direction of magnetization is fixed;
two free layers each configured to be capable of including a magnetic vortex structure and configured so that a center of the magnetic vortex structure can move in accordance with a target magnetic field, and
a gap layer arranged between the magnetization pinned layer and the two free layers, wherein
the magnetization pinned layer includes a first region and a second region in which the directions of the magnetization are less aligned than the first region, and
each of the two free layers is arranged so that an area of an overlapping part in which each of the two free layers and the first region overlap each other when viewed in a stacking direction of the magnetization pinned layer, the gap layer, and the two free layers is larger than an area of an overlapping part in which each of the two free layers and the second region overlap each other when viewed in the stacking direction.

18. A magnetic sensor comprising:
a power supply port;
a ground port;
an output port;
a first resistor section arranged between the power supply port and the output port; and
a second resistor section arranged between the ground port and the output port, wherein
each of the first resistor section and the second resistor section includes a plurality of magnetism detection elements, and
each of the plurality of magnetism detection elements is the magnetoresistive element according to claim 1.

19. A magnetic sensor configured to detect a target magnetic field and generate at least one detection signal, the magnetic sensor comprising:
a power supply port;
a ground port;
an output port;
a first resistor section arranged between the power supply port and the output port; and
a second resistor section arranged between the ground port and the output port, wherein
each of the first resistor section and the second resistor section includes a plurality of magnetoresistive elements,
each of the plurality of magnetoresistive elements includes
a magnetization pinned layer in which a direction of magnetization is fixed,
a free layer configured to be capable of including a magnetic vortex structure and configured so that a center of the magnetic vortex structure can move in accordance with the target magnetic field, and
a gap layer arranged between the magnetization pinned layer and the free layer,
a planar shape of the magnetization pinned layer is larger than a planar shape of the free layer,
the at least one detection signal has correspondence with a potential of the output port, and has a specific value in a state in which strength of the target magnetic field is zero, and
each of the plurality of magnetoresistive elements is configured so that a difference between the specific value before a strong magnetic field other than the target magnetic field is temporarily applied to the magnetic sensor and the specific value after the strong magnetic field is temporarily applied is smaller than a difference in a case in which the planar shape of the magnetization pinned layer is assumed to be same as the planar shape of the free layer.
